(19) United States
(12) Patent Application Publication
(10) Pub. No.: US 2025/0248188 A1
(43) Pub. Date: Jul. 31, 2025

(54) LIGHT EMITTING DIODE, MANUFACTURING METHOD FOR THE SAME, DISPLAY DEVICE INCLUDING LIGHT EMITTING DIODE, AND MANUFACTURING METHOD FOR THE SAME

(71) Applicant: SAMSUNG DISPLAY CO., LTD., Yongin-si (KR)

(72) Inventors: Chang Hee LEE, Yongin-si (KR); Young Il KIM, Yongin-si (KR); Hyo Jin KO, Yongin-si (KR); Dong Hoon KWAK, Yongin-si (KR); Dong Uk KIM, Yongin-si (KR); Se Hun KIM, Yongin-si (KR); Ji Yoon KIM, Yongin-si (KR)

(21) Appl. No.: 19/067,464

(22) Filed: Feb. 28, 2025

Related U.S. Application Data
(63) Continuation of application No. 17/445,801, filed on Aug. 24, 2021.

(30) Foreign Application Priority Data
Jan. 14, 2021 (KR) 10-2021-0005573

(51) Int. Cl. H10H 20/857; H01L 25/075; H10D 86/40; H10D 86/60; H10H 20/01; H10H 20/821

(52) U.S. Cl. CPC H10H 20/857; H01L 25/0753; H10D 86/40; H10D 86/60; H10H 20/018; H10H 20/821; H10H 20/0364

(57) ABSTRACT

A light emitting diode includes: a first semiconductor layer; an active layer located on one surface of the first semiconductor layer; a second semiconductor layer located on one surface of the active layer; an electrode layer located on one surface of the second semiconductor layer; and a bonding electrode layer located on the other surface of the first semiconductor layer.

### CROSS-REFERENCE TO RELATED APPLICATION

This application is a continuation of U.S. application Ser. No. 17/445,801 filed on Aug. 24, 2021, which claims priority to and the benefit of Korean patent application 10-2021-0005573, filed on Jan. 14, 2021 in the Korean Intellectual Property Office, the entire contents of both of which are incorporated herein by reference.

### BACKGROUND

### 1. Field

One or more embodiments of the present disclosure generally relate to a light emitting diode, a manufacturing method for the same, a display device include a light emitting diode, and a manufacturing method for the same.

### 2. Related Art

As interest in information displays and demand for portable information media increase, research and commercialization has focused on display devices.

### SUMMARY

One or more embodiments of the present disclosure provide a light emitting diode, a manufacturing method for the same, a display device include a light emitting diode, and a manufacturing method for the same, which have improved luminance, lifetime, yield, and/or the like.

In accordance with one or more embodiments of the present disclosure, there is provided a light emitting diode including: a first semiconductor layer; an active layer on one surface of the first semiconductor layer; a second semiconductor layer on one surface of the active layer; an electrode layer on one surface of the second semiconductor layer; and a bonding electrode layer on another surface of the first semiconductor layer.

The bonding electrode layer may include at least one selected from a metal having a melting point of about 300° C. or lower, a fusible alloy, an eutectic alloy, and a soldering metal to mount a semiconductor chip.

The first semiconductor layer may include at least one n-type semiconductor, and the second semiconductor layer may include at least one p-type semiconductor. The bonding electrode layer may be under the first semiconductor layer, and the electrode layer may be on the second semiconductor layer.

The first semiconductor layer may include at least one p-type semiconductor, and the second semiconductor layer may include at least one n-type semiconductor. The bonding electrode layer may be under the first semiconductor layer, and the electrode layer may be on the second semiconductor layer.

The light emitting diode may have a shape in which a width in a horizontal direction thereof is longer than a height in a vertical direction thereof.

In accordance with one or more embodiments of the present disclosure, there is provided a display device including: a base layer; a pixel circuit layer on the base layer, the pixel circuit layer including a first transistor; and a display element layer on the pixel circuit layer, the display element layer including a light emitting diode, a first electrode to which a first driving voltage is applied, and a second electrode to which a second driving voltage is applied, wherein the light emitting diode includes: a first semiconductor layer; an active layer is on one surface of the first semiconductor layer; a second semiconductor layer on one surface of the active layer; an electrode layer on one surface of the second semiconductor layer; and a bonding electrode layer on another surface of the first semiconductor layer, and wherein the electrode layer is electrically coupled to the second electrode, and the bonding electrode layer is electrically coupled to the first electrode.

The first semiconductor layer may include one selected from at least one n-type semiconductor and at least one p-type semiconductor, and the second semiconductor layer may include another one selected from the at least one p-type semiconductor and the at least one n-type semiconductor.

The first transistor may include a gate electrode, an active layer, a source electrode, and a drain electrode. The drain electrode of the first transistor may be electrically coupled to the first electrode.

The bonding electrode layer may be on the first electrode. The first electrode and the bonding electrode layer may be in direct contact with each other.

The bonding electrode layer may include at least one selected from a metal having a melting point of about 300° C. or lower, a fusible alloy, an eutectic alloy, and a soldering metal to mount a semiconductor chip.

The electrode layer may be under the second electrode. The second electrode and the electrode layer may be in direct contact with each other.

In accordance with one or more embodiments of the present disclosure, there is provided a method for manufacturing a light emitting diode, the method including: sequentially forming, on a stack substrate, a first sacrificial layer, a light emitting stack structure, a second sacrificial layer, and a first bonding layer; forming a second bonding layer on a carrier substrate, and bonding the first bonding layer and the second bonding layer to each other; removing the stack substrate and the first sacrificial layer; etching the light emitting stack structure in one direction; forming a photoresist pattern at both side surfaces of the light emitting stack structure, and forming a bonding electrode layer on each of the formed photoresist pattern and the light emitting stack structure; removing the photoresist pattern and the bonding electrode layer formed on the photoresist pattern; and forming a light emitting diode comprising the bonding electrode layer formed on the etched light emitting stack structure by removing the carrier substrate, the first bonding layer, the second bonding layer, and the second sacrificial layer.

The light emitting stack structure may include: a first semiconductor layer; an active layer on one surface of the first semiconductor layer; a second semiconductor layer on one surface of the active layer; and an electrode layer on one surface of the second semiconductor layer.

The bonding electrode layer may include at least one selected from a metal having a melting point of about 300° C. or lower, a fusible alloy, an eutectic alloy, and a soldering metal to mount a semiconductor chip.

In one or more embodiments, the photoresist pattern may be coated to at least partially overlap with both side surfaces of the light emitting stack structure and an upper surface of the light emitting stack structure, and the bonding electrode layer may be formed on each of the photoresist pattern and the light emitting stack structure. In the forming of the light emitting diode, the light emitting diode may be formed, in which both side edges of the light emitting stack structure and both side edges of the bonding electrode layer are located on a respective straight line having the same slope.

In accordance with one or more embodiments of the present disclosure, there is provided a method for manufacturing a display device, the method including: forming a first electrode on a base layer, and spraying an ink including a plurality of light emitting diodes and a solvent onto the first electrode; aligning the plurality of light emitting diodes on the first electrode, and volatilizing the solvent; and bonding the plurality of light emitting diodes and the first electrode to each other via a bonding electrode layer that is in direct contact with the first electrode.

Each of the plurality of light emitting diodes may include: a first semiconductor layer; an active layer on one surface of the first semiconductor layer; a second semiconductor layer on one surface of the active layer; and an electrode layer on one surface of the second semiconductor layer. The bonding electrode layer may be on another surface of the first semiconductor layer.

The bonding electrode layer may include at least one selected from a metal having a melting point of about 300° C. or lower, a fusible alloy, an eutectic alloy, and a soldering metal to mount a semiconductor chip.

A heating part may be under the base layer, and the plurality of light emitting diodes and the first electrode may be bonded to each other via the bonding electrode layer by applying heat.

The plurality of light emitting diodes and the first electrode may be bonded to each other via the bonding electrode layer by irradiating laser between the bonding electrode layer and the first electrode.

### BRIEF DESCRIPTION OF THE DRAWINGS

Embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the embodiments to those skilled in the art.

In the drawing figures, dimensions may be exaggerated for clarity of illustration. Like reference numerals refer to like elements throughout.

FIGS. 1 and 2 are cross-sectional views illustrating light emitting diodes in accordance with one or more embodiments of the present disclosure.

FIG. 3 is a perspective view illustrating a light emitting diode in accordance with one or more embodiments of the present disclosure.

FIG. 4 is a plan view schematically illustrating a display device in accordance with one or more embodiments of the present disclosure.

FIG. 5 is a circuit diagram of a pixel of the display device in accordance with one or more embodiments of the present disclosure.

FIG. 6 is a schematic cross-sectional view of a display device in accordance with one or more embodiments of the present disclosure.

FIGS. 7 to 17 are cross-sectional views illustrating a manufacturing method for a light emitting diode and a manufacturing method for a display device including the light emitting diode in accordance with one or more embodiments of the present disclosure.

FIG. 18 is a schematic cross-sectional view of a light emitting diode and a display device including the same in accordance with one or more embodiments of the present disclosure.

### DETAILED DESCRIPTION

The present disclosure may embody various changes and modifications, therefore it only illustrates in details certain examples. However, the examples are not limited to what is illustrated, but rather include all the changes and equivalent materials and replacement. The drawings included are illustrated in a fashion where the elements and dimensions are expanded (exaggerated) for the better understanding.

Like numbers refer to like elements throughout. In the drawings, the thickness of certain lines, layers, components, elements or features may be exaggerated for clarity. It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

It will be understood that when an element is referred to as being “between” two elements, it can be the only element between the two elements, or one or more intervening elements may also be present.

It will be further understood that the terms “includes,” “comprise,” “comprising,” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element (without any intervening elements therebetween), but also a case where a further element is interposed between the element and the other element. Similarly, an expression that an element such as a layer, region, substrate or plate is placed “beneath” or “below” another element indicates not only a case where the element is placed “directly beneath” or “just below” the other element (without any intervening elements therebetween), but also a case where a further element is interposed between the element and the other element. Further, as used herein, the term “direct contact” may also mean direct physical contact.

In this specification, the terms “upper surface” and “lower surface” are defined based on a direction shown in the drawings, and hence directions indicated by the “upper surface” and “lower surface” may be opposite to each other according to an actual position of each component. For example, the “upper surface” of this specification may actually correspond to the “lower surface,” and the “lower surface” of this specification may actually correspond to the “upper surface.”

As used herein, the singular forms “a,” “an,” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list.

As used herein, the term “and/or” includes any and all combinations of one or more of the associated listed items. Further, the use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinafter, a light emitting diode, a manufacturing method for the same, a display device including a light emitting diode, and a manufacturing method for the same in accordance with embodiments of the present disclosure will be described with reference to the accompanying drawings.

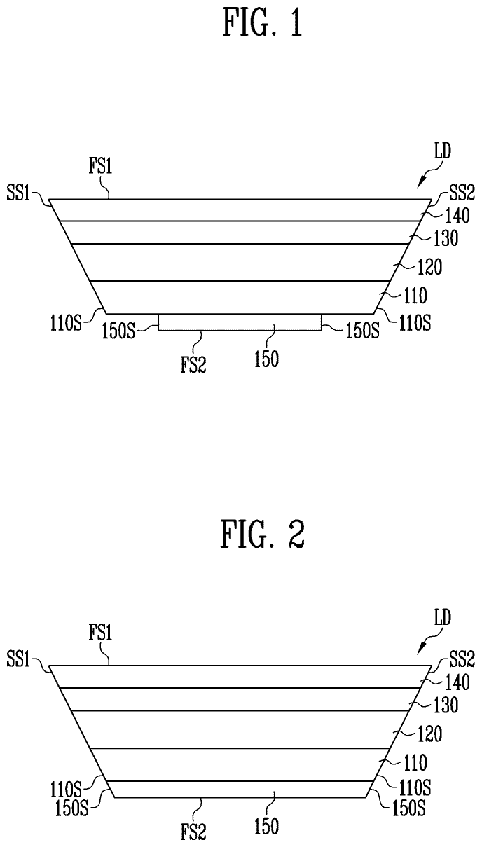

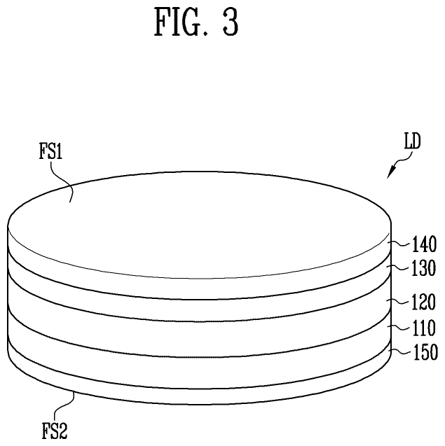

FIGS. 1 and 2 are cross-sectional views illustrating light emitting diodes in accordance with embodiments of the present disclosure. FIG. 3 is a perspective view illustrating a light emitting diode in accordance with one or more embodiments of the present disclosure.

Referring to FIGS. 1 to 3, each of the light emitting diodes LD in accordance with the embodiments of the present disclosure may include a first semiconductor layer 110, an active layer 120, a second semiconductor layer 130, an electrode layer 140, and a bonding electrode layer 150. In an example, the light emitting diode LD may be configured as a stack structure in which the bonding electrode layer 150, the first semiconductor layer 110, the active layer 120, the second semiconductor layer 130, and the electrode layer 140 are sequentially stacked along a height (or length) direction thereof.

Along the height direction of the light emitting diode LD, an upper surface of the light emitting diode LD may be referred to as a first surface FS1, and a lower surface of the light emitting diode LD may be referred to as a second surface FS2. In one or more embodiments, the electrode layer 140 may be at the first surface FS1 of the light emitting diode LD, and the bonding electrode layer 150 may be at the second surface FS2 of the light emitting diode LD. In one or more embodiments, the bonding electrode layer 150 may be at the first surface FS1 of the light emitting diode LD, and the electrode layer 140 may be at the second surface FS2 of the light emitting diode LD.

Each of the first surface FS1 and the second surface FS2 of the light emitting diode LD may be implemented in a set or predetermined shape. For example, each of the first surface FS1 and the second surface FS2 of the light emitting diode LD may be implemented in a circular shape or an elliptical shape. In one or more embodiments, each of the first surface FS1 and the second surface FS2 of the light emitting diode LD may be implemented in a polygonal shape such as a rectangular shape, a square shape, a regular triangular shape, or a regular pentagonal shape.

Referring to FIG. 3, each of the first surface FS1 and the second surface FS2 of the light emitting diode LD may be implemented in a circular shape or an elliptical shape. An area of the upper surface of the light emitting diode LD and an area of the lower surface of the light emitting diode LD may be the same. For example, the light emitting diode LD may have a cylindrical shape. In one or more embodiments, the light emitting diode LD may have a coin shape in which the width of the light emitting diode LD is longer than the height of the light emitting diode LD.

The light emitting diode LD may have a set or predetermined shape, and an area of the upper surface of the light emitting diode LD and an area of the lower surface of the light emitting diode LD may be different from each other. Areas of sections of the light emitting diode LD may be different from each other along a width (or breadth) direction. For example, an area of the first surface FS1 of the light emitting diode LD and an area of the second surface FS2 of the light emitting diode LD may be different from each other. Accordingly, in one or more embodiments, the light emitting diode LD may have a truncated pyramid shape in which an area of an upper surface and an area of a lower surface are difference from each other as shown in FIGS. 1 and 2.

The light emitting diode LD may have a nanometer scale to micrometer scale size. However, the size of the light emitting diode LD is not limited thereto, and may be variously suitably changed according to design conditions of various devices (e.g., a display device and/or the like) using, as a light source, a light emitting device using the light emitting diode LD.

The first semiconductor layer 110 may be a semiconductor layer having a first conductivity (or type). In an example, the first semiconductor layer 110 may include at least one n-type semiconductor. For example, the first semiconductor layer 110 may include any one semiconductor material selected from among InAlGaN, GaN, AlGaN, InGaN, AlN, and InN, and include an n-type semiconductor layer doped with a first conductive dopant such as Si, Ge and/or Sn. However, the material constituting the first semiconductor layer 110 is not limited thereto. In one or more embodiments, various suitable materials may constitute the first semiconductor layer 110.

In some embodiments, the first semiconductor layer 110 may be a semiconductor layer having a second conductivity (or type). In an example, the first semiconductor layer 110 may include at least one p-type semiconductor. For example, the first semiconductor layer 110 may include at least one semiconductor material selected from among InAlGaN, GaN, AlGaN, InGaN, AlN, and InN, and include a p-type semiconductor layer doped with a second conductive dopant such as Mg, Zn, Ca, Sr and/or Ba.

The active layer 120 may be on one surface of the first semiconductor layer 110. The active layer 120 may be on the first semiconductor layer 110. The active layer 120 may be formed in a single or multiple quantum well structure. In one or more embodiments, a clad layer doped with a conductive dopant may be formed on the top and/or the bottom of the active layer 120. In an example, the clad layer may be formed as an AlGaN layer and/or an InAlGaN layer. In some embodiments, a material such as AlGaN and/or InAlGaN may be used to form the active layer 120. In one or more embodiments, various suitable materials may constitute the active layer 120.

When a voltage equal to or higher than a threshold voltage is applied to the upper surface and the lower surface of the light emitting diode LD, the light emitting diode LD emits light as electron-hole pairs are combined in the active layer 120. The light emission of the light emitting diode LD is controlled by using such a principle, so that the light emitting diode LD can be used as a light source for various suitable light emitting devices, including a pixel of a display device.

The second semiconductor layer 130 is formed on one surface of the active layer 120. The second semiconductor layer 130 may be on the active layer 120. The second semiconductor layer 130 may include a semiconductor layer having a conductivity (or type) different from that of the first semiconductor layer 110. In an example, the second semiconductor layer 130 may include at least one p-type semiconductor layer. For example, the second semiconductor layer 13 may include at least one semiconductor material selected from among InAlGaN, GaN, AlGaN, InGaN, AlN, and InN, and include a p-type semiconductor layer doped with a second conductive dopant (or p-type dopant) such as Mg, Zn, Ca, Sr and/or Ba. However, the material constituting the second semiconductor layer 130 is not limited thereto. In one or more embodiments, various suitable materials may constitute the second semiconductor layer 130.

In some embodiments, the second semiconductor layer 130 may include at least one n-type semiconductor. For example, the second semiconductor layer 130 may include any one semiconductor material selected from among InAlGaN, GaN, AlGaN, InGaN, AlN, and InN, and include an n-type semiconductor layer doped with a first conductive dopant such as Si, Ge and/or Sn.

The electrode layer 140 is on one surface of the second semiconductor layer 130. The electrode layer 140 may be on the second semiconductor layer 130. The electrode layer 140 may include metal or metal oxide. In an example, the electrode layer 140 may include at least one selected from Cr, Ti, Al, Au, Ni, ITO, IZO, ITZO, any oxide thereof, and any alloy thereof. In one or more embodiments, the electrode layer 140 may include at least one selected from a metal which has an excellent (or suitable) electrical characteristic and a melting point of about 300° C. or lower, a fusible alloy, an eutectic alloy, and a soldering metal (e.g., a soldering metal for mounting a semiconductor chip). For example, the electrode layer 140 may include at least one selected from Sn, Bi, In, Ga, Sb, Pb, Cd, and any alloy thereof.

In some embodiments, the electrode layer 140 may be substantially transparent or translucent. Accordingly, light generated in the light emitting diode LD may be transmitted through the electrode layer 140 and then emitted to the outside of the light emitting diode LD. The electrode layer 140 may be in direct contact with a second electrode (e.g., a cathode) of a pixel which will be described in more detail below.

The bonding electrode layer 150 is on one surface of the first semiconductor layer 110. The bonding electrode layer 150 may be under the first semiconductor layer 110.

As shown in FIG. 1, a side edge 150S of the bonding electrode layer 150 may be located not to get out of (e.g., not to surpass or not to extend past) a side edge 110S of the first semiconductor layer 110. Both side edges 150S of the bonding electrode layer 150 may be located inward of (e.g., between) both side edges 110S of the first semiconductor layer 110. Accordingly, both the side edges 150S of the bonding electrode layer 150 may be located not to get out of (e.g., not to surpass) a first side surface SS1 and a second side surface SS2 of the light emitting diode LD.

As shown in FIG. 2, the side edge 150S of the bonding electrode layer 150 may accord with (e.g., may be aligned with) the side edge 110S of the first semiconductor layer 110. Accordingly, the first semiconductor layer 110, the active layer 120, the second semiconductor layer 130, the electrode layer 140, and the side edges 150S of the bonding electrode layer 150 may be located on a straight line having the same slope at the first side surface SS1 and the second side surface SS2, respectively, of the light emitting diode LD.

The bonding electrode layer 150 may include a metal and/or a metal oxide. In an example, the bonding electrode layer 150 may include at least one selected from a metal which has an excellent (or suitable) electrical characteristic and a melting point of about 300° C. or lower, a fusible alloy, and an eutectic alloy. For example, the bonding electrode layer 150 may include at least one selected from Sn, Bi, In, Ga, Sb, Pb, Cd, and any alloy thereof. The bonding electrode layer 150 may also include a soldering metal (e.g., a soldering metal for mounting a semiconductor chip). In one or more embodiments, the bonding electrode layer 150 may include at least one selected from Cr, Ti, Al, Au, Ni, ITO, IZO, ITZO, any oxide thereof, and any alloy thereof. For example, the electrode layer 140 and the bonding electrode layer 150 may include the same material or include different materials.

In some embodiments, the bonding electrode layer 150 may be substantially transparent or translucent. Accordingly, light generated in the light emitting diode LD may be transmitted through the bonding electrode layer 150 and then emitted to the outside of the light emitting diode LD. The electrode layer 140 may be in direct contact with a first electrode (e.g., an anode) or the second electrode (e.g., the cathode) of the pixel which will be described in more detail below. For example, because the bonding electrode layer 150 is in direct contact with the first electrode or the second electrode of the pixel, the bonding electrode layer 150 can stably transfer a driving voltage and/or current to the first semiconductor layer 110, etc. of the light emitting diode LD. Accordingly, the bonding force between the light emitting diode LD and the first or second electrode is improved, so that the display device having improved luminance, improved lifetime, improved yield, and/or the like can be implemented.

The electrode layer 140 and the bonding electrode layer 150 may each independently be an ohmic contact electrode or a Schottky contact electrode, but the present disclosure is not limited thereto.

In one or more embodiments, the electrode layer 140 and the bonding electrode layer 150 may be in contact with any one selected from the first electrode and the second electrode according to types (e.g., conductivity types) of the first semiconductor layer 110 and the second semiconductor layer 130.

In an example, when the first semiconductor layer 110 includes an n-type semiconductor layer and the second semiconductor layer 130 includes a p-type semiconductor layer, the bonding electrode layer 150 is in direct contact with the first electrode of the pixel, so that the bonding force between the light emitting diode LD and the first electrode can be improved. In one or more embodiments, the electrode layer 140 is in direct contact with the second electrode of the pixel, so that the bonding force between the light emitting diode LD and the second electrode can be improved.

In another example, when the first semiconductor layer 110 includes a p-type semiconductor layer and the second semiconductor layer 130 includes an n-type semiconductor layer, the bonding electrode layer 150 is in direct contact with the second electrode of the pixel, so that the bonding force between the light emitting diode LD and the second electrode can be improved. In one or more embodiments, the electrode layer 140 is in direct contact with the first electrode of the pixel, so that the bonding force between the light emitting diode LD and the first electrode can be improved.

In the above-described embodiment, it is illustrated that each of the first semiconductor layer 110 and the second semiconductor layer 130 is configured with one layer, but the present disclosure is not limited thereto. In one or more embodiments, each of the first semiconductor layer 110 and the second semiconductor layer 130 may further include at least one layer, e.g., a clad layer and/or a Tensile Strain Barrier Reducing (TSBR) layer according to the material of the active layer 120. The TSBR layer may be a strain reducing layer between semiconductor layers having different lattice structures to perform a buffering function for reducing a lattice constant difference. The TSBR may be configured with a p-type semiconductor layer such as p-GAInP, p-AlInP and/or p-AlGaInP, but the present disclosure is not limited thereto.

In one or more embodiments, the light emitting diode LD may further include an additional component in addition to the first semiconductor layer 110, the active layer 120, the second semiconductor layer 130, the electrode layer 140, and the bonding electrode layer 150.

In some embodiments, the light emitting diode LD may further include an insulative film provided on a surface thereof. The insulative film may be formed on the surface of the light emitting diode LD to surround an outer circumferential surface of the active layer 120. In one or more embodiments, the insulative film may further surround one area of the first semiconductor layer 110, the second semiconductor layer 130, the electrode layer 140, and the bonding electrode layer 150. However, the insulative film may expose the upper surface and the lower surface of the light emitting diode LD, which have different polarities. For example, the insulative film does not cover one end of each of the first semiconductor layer 110 and the second semiconductor layer 130, which are located at both ends of the light emitting diode LD along the height direction, e.g., two surfaces (the upper surface and the lower surface) of the light emitting diode LD, but may expose the one end of each of the first semiconductor layer 110 and the second semiconductor layer 130. When the insulative film is provided on the surface of the light emitting diode LD, particularly, a surface of the active layer 120, the risk of a short-circuit of the active layer 120 with at least one electrode can be prevented or reduced. Accordingly, the electrical stability of the light emitting diode LD can be ensured (or improved).

In one or more embodiments, the insulative film is formed on the surface of the light emitting diode LD, so that a surface defect of the light emitting diode LD is minimized or reduced, so that the lifetime and efficiency of the light emitting diode LD can be improved. In one or more embodiments, when the insulative film is formed on each light emitting diode LD, the risk of an unwanted short-circuit between a plurality of light emitting diodes LD, that may occur when the plurality of light emitting diodes LD are adjacent to each other, can be prevented or reduced.

In one or more embodiments of the present disclosure, the light emitting diode LD may be manufactured through a surface treatment process. For example, when a plurality of light emitting diodes LD are mixed in a liquid solution (or solvent) to be supplied to each emission area (e.g., an emission area of each pixel), each light emitting element LD may be surface-treated such that the light emitting elements LD are not unequally condensed in the solution but substantially equally dispersed in the solution.

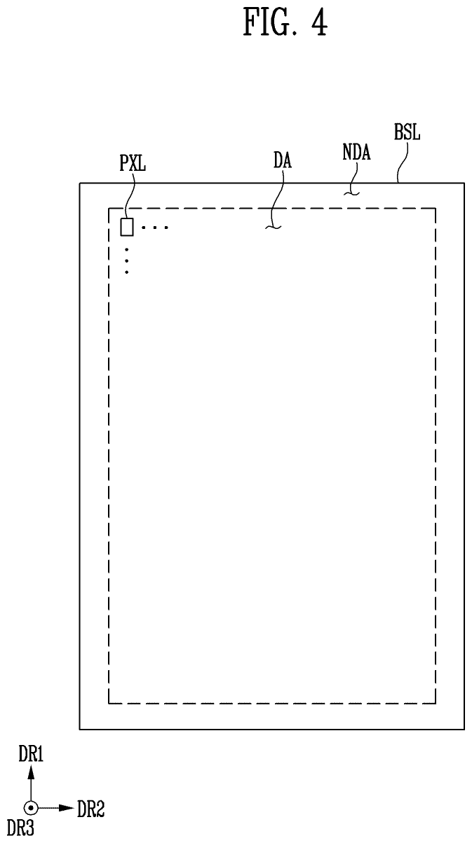

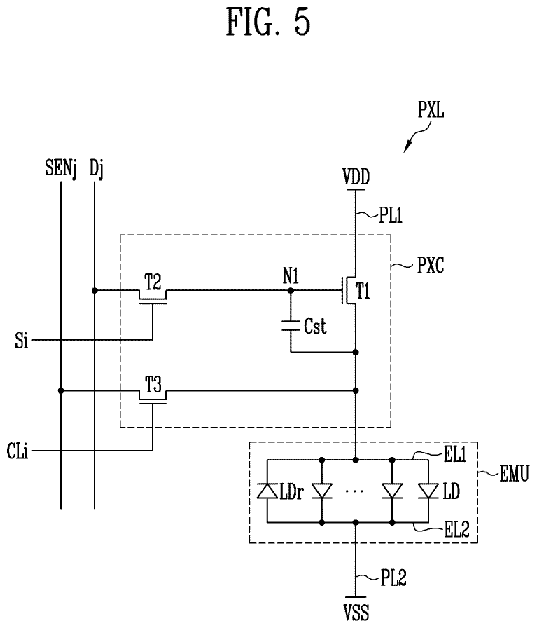

Hereinafter, a display device and a pixel included in the display device in accordance with one or more embodiments of the present disclosure will be described with reference to FIGS. 4 and 5.

FIG. 4 is a plan view schematically illustrating a display device in accordance with one or more embodiments of the present disclosure. FIG. 5 is a circuit diagram of a pixel of the display device in accordance with one or more embodiments of the present disclosure.

First, referring to FIG. 4, the display device in accordance with the embodiments of the present disclosure may include a base layer BSL and a plurality of pixels PXL on the base layer BSL.

The base layer BSL may constitute a base member of the display device. In some embodiments, the base layer BSL may be a rigid or flexible substrate or a film, and the material and/or property of the base layer BSL are not particularly limited. In an example, the base layer BSL may be a rigid substrate made of glass or tempered glass, a flexible substrate (or thin film) made of a plastic or metal material, and/or at least one insulating layer, and the material and/or property of the base layer BSL are not particularly limited. In one or more embodiments, the base layer BSL may be transparent, but the present disclosure is not limited thereto. In an example, the base layer BSL may be a transparent, translucent, opaque or reflective base member.

The base layer BSL may include a display area DA in which an image is displayed and a non-display area NDA outside the display area DA. The non-display area NDA may be a bezel area surrounding the display area DA.

The pixels PXL may be in the display area DA. The pixel PXL may include the light emitting diode (LD shown in FIGS. 1 to 3). The pixels PXL may be regularly arranged (e.g., at regular intervals) according to a stripe or PenTile®/PENTILE® arrangement structure (PENTILE® is a registered trademark owned by Samsung Display Co., Ltd.). However, the arrangement structure of the pixels PXL is not limited thereto, and the pixels PXL may be arranged in the display area DA in various suitable structures and/or various suitable manners.

Various lines, pads, and/or a circuit unit, which are connected (e.g., electrically coupled) to the pixels PXL of the display area DA, may be in the non- display area NDA.

Referring to FIG. 5, the pixel PXL may include a pixel circuit PXC and a light emitting unit EMU.

The pixel circuit PXC may include a first transistor T1 (driving transistor), a second transistor T2, a third transistor T3, and a storage capacitor Cst.

A first electrode of the first transistor T1 may be connected (e.g., electrically coupled) to a first power source VDD through a first voltage line PL1, and a second electrode of the first transistor T1 may be connected (e.g., electrically coupled) to a first electrode EL1 of the light emitting diode LD. A gate electrode of the first transistor T1 may be connected (e.g., electrically coupled) to a first node N1. The first transistor T1 may control an amount of current flowing through the light emitting diode LD, corresponding to a voltage of the first node N1.

A first electrode of the second transistor T2 may be connected (e.g., electrically coupled) to a data line Dj, and a second electrode of the second transistor T2 may be connected (e.g., electrically coupled) to the first node N1. A gate electrode of the second transistor T2 may be connected (e.g., electrically coupled) to a scan line Si. The second transistor T2 may be turned on when a scan signal is supplied to the scan line Si, to transfer a data signal from the data line Dj to the first node N1.

The third transistor T3 may be connected (e.g., electrically coupled) between a sensing line SENj and the second electrode of the first transistor T1. A gate electrode of the third transistor T3 may be connected (e.g., electrically coupled) to a control line CLi. The third transistor T3 may be turned on when a control signal is supplied to the control line CLi, to electrically connect (e.g., electrically couple) the sensing line SENj and the second electrode of the first transistor T1 to each other. In one or more embodiments, when the third transistor T3 is turned on, an initialization voltage may be supplied to the second electrode of the first transistor T1.

The storage capacitor Cst may be connected (e.g., electrically coupled) between the first node N1 and the second electrode of the first transistor T1. The storage capacitor Cst may store a voltage corresponding to a voltage difference between the first node N1 and the second electrode of the first transistor T1.

The light emitting unit EMU may include a plurality of light emitting diodes LD connected (e.g., electrically coupled) in parallel between the pixel circuit PXC and a second power source VSS. The light emitting unit EMU may be connected (e.g., electrically coupled) to the second power source VSS through a second voltage line PL2. The plurality of light emitting diode LD may be connected (e.g., electrically coupled) in parallel between the first electrode EL1 and a second electrode EL2. The first electrode EL1 may be an anode, and the second electrode EL2 may be a cathode. However, the present disclosure is not limited thereto, and the first electrode EL1 and the second electrode EL2 may be the cathode and the anode, respectively.

The light emitting unit EMU may include at least one light emitting diode LD aligned in a first direction and a least one light emitting diode LDr aligned in a second direction opposite to the first direction.

The first power source VDD and the second power source VSS may have different potentials such that the light emitting diodes LD can emit light. In an example, the first power source VDD may be set as a high-potential power source, and the second power source VSS may be set as a low-potential power source. A potential difference between the first and second power sources VDD and VSS may be set to a threshold voltage of the light emitting diodes or higher during at least an emission period of the pixel PXL. Accordingly, each light emitting unit EMU may emit light with a luminance corresponding to a driving current supplied through the pixel circuit PXC.

In the embodiments of the present disclosure, the circuit structure of the pixel PXL is not limited by FIG. 5. In an example, the light emitting diode LD may be located between the first power source VDD and the first electrode of the first transistor T1.

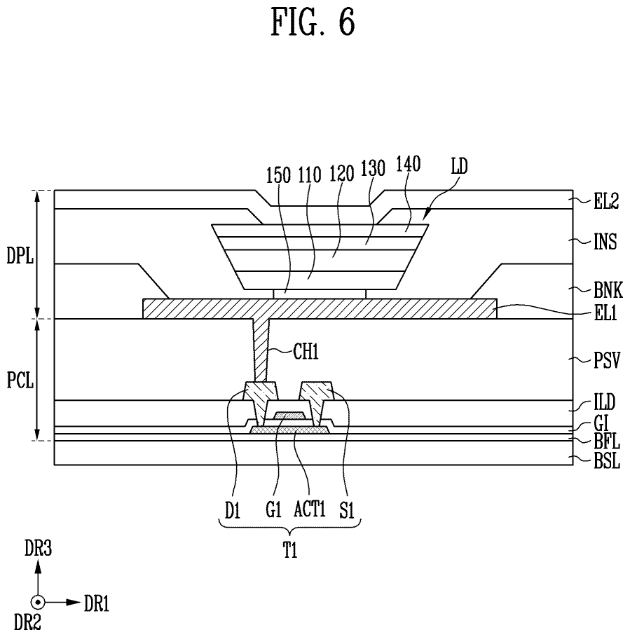

Hereinafter, a structure of s display device in accordance with one or more embodiments of the present disclosure will be described with reference to FIG. 6.

FIG. 6 is a schematic cross-sectional view of a display device in accordance with one or more embodiments of the present disclosure.

Referring to FIG. 6, the display device may include a base layer BSL, a pixel circuit layer PCL, and a display element layer DPL.

The base layer BSL may be a rigid or flexible substrate. For example, the rigid substrate may be made of glass, quartz and/or the like, and the flexible substrate may include at least one material selected from among polyimide, polycarbonate, polystyrene, and polyvinyl alcohol. However, the embodiments of the present disclosure are not limited thereto.

The pixel circuit layer PCL is located on the base layer BSL. The pixel circuit layer PCL may include a buffer layer BFL, a first transistor T1, a gate insulating layer GI, an interlayer insulating layer ILD, and a passivation layer PSV.

The buffer layer BFL is located on the base layer BSL. The buffer layer BFL may prevent or reduce the diffusion of impurities from the outside. The buffer layer BFL may include at least one selected from silicon nitride (SiNx), silicon oxide (SiOx), silicon oxynitride (SiOxNy), and metal oxide such as aluminum oxide (AlOx). In some embodiments, the buffer layer BFL may be omitted.

The first transistor T1 may include an active layer ACT1, a gate electrode G1, a source electrode S1, and a drain electrode D1. The first transistor T1 may be the above-described driving transistor shown in FIG. 5.

The active layer ACT1 is located on the buffer layer BFL. The active layer ACT1 may include at least one selected from poly-silicon, amorphous silicon, and an oxide semiconductor.

The active layer ACT1 may include a first source region connected (e.g., electrically coupled) to the source electrode S1, a first drain region connected (e.g., electrically coupled) to the drain electrode D1, and a channel region between the first source region and the first drain region.

The gate insulating layer GI is located over the active layer ACT1, and is located to cover the active layer ACT1 and the buffer layer BFL. The gate insulating layer GI may include an inorganic material. In an example, the gate insulating layer GI may include at least one selected from silicon nitride (SiNx), silicon oxide (SiOx), silicon oxynitride (SiOxNy), and aluminum oxide (AlOx). In some embodiments, the gate insulating layer GI may include an organic material.

The gate electrode G1 is located on the gate insulating layer GI. The gate electrode G1 may be located to overlap with the channel region of the active layer ACT1.

The interlayer insulating layer ILD is located over the gate electrode G1, and is located to cover the gate electrode G1 and the gate insulating layer GI. The interlayer insulating layer ILD may include the same material as the gate insulating layer GI. In an example, the interlayer insulating layer ILD may include at least one selected from silicon nitride (SiNx), silicon oxide (SiOx), silicon oxynitride (SiOxNy), and aluminum oxide (AlOx).

The source electrode S1 and the drain electrode D1 are located on the interlayer insulating layer ILD. The source electrode S1 may be in contact (e.g., physical and/or electrical contact) with the first source region of the active layer ACT1 while penetrating the gate insulating layer GI and the interlayer insulating layer ILD, and the drain electrode D1 may be in contact (e.g., physical and/or electrical contact) with the first drain region of the active layer ACT1 while penetrating the gate insulating layer GI and the interlayer insulating layer ILD.

The passivation layer PSV is located overt the source electrode S1 and the drain electrode D1, and is located to cover the source electrode S1, the drain electrode D1, and the interlayer insulating layer ILD. The passivation layer PSV may include an inorganic material and/or an organic material.

The drain electrode D1 of the first transistor T1 and a first electrode EL1 of the display element layer DPL may be physically and/or electrically connected (e.g., physically and/or electrically coupled) to each other through a first contact hole CH1 of the passivation layer PSV.

The display element layer DPL is located on the pixel circuit layer PCL. The display element layer DPL may include the first electrode EL1, a bank BNK, a light emitting diode LD, an insulating layer INS, and a second electrode EL2.

The first electrode EL1 is located on the passivation layer PSV of the pixel circuit layer PCL. The first electrode EL1 may be an anode. The first electrode EL1 may be physically and/or electrically connected (e.g., physically and/or electrically coupled) to the drain electrode D1 of the pixel circuit layer PCL through the first contact hole CH1 of the passivation layer PSV. Accordingly, the first electrode EL1 may be applied with a voltage of the first power source (VDD shown in FIG. 5).

The first electrode EL1 may include a transparent conductive material. In an example, the first electrode EL1 may include Cu, Au, Ag, Mg, Al, Pt, Pb, Ni, Nd, Ir, Cr, Li, Ca, any mixture thereof, ITO, IZO, ZnO, ITZO, etc., but the present disclosure is not limited thereto.

The bank BNK may be located on the passivation layer PSV of the pixel circuit layer PCL. The bank BNK may be a structure capable of partitioning each pixel area. The first electrode EL1, the light emitting diode LD, and/or the like may be located between two adjacent banks BNK. The bank BNK may include an organic material.

The light emitting diode LD is located on the first electrode EL1. In one or more embodiments, a bonding electrode layer 150 of the light emitting diode LD may be located on the first electrode EL1, and the first electrode EL1 and the bonding electrode layer 150 of the light emitting diode LD may be in direct contact with each other. Accordingly, a first driving voltage of the first power source (VDD shown in FIG. 5), which is applied to the first electrode EL1, can be transferred to the light emitting diode LD. In one or more embodiments, because the first electrode EL1 is in direct contact with the bonding electrode layer 150 of the light emitting diode LD, a driving voltage and/or current can be stably (or suitably) transferred to a first semiconductor layer 110 and/or the like of the light emitting diode LD. Accordingly, the bonding force between the light emitting diode LD and the first electrode EL1 is improved, so that the display device having improved luminance, improved lifetime, improved yield, and/or the like can be implemented.

The insulating layer INS is located over the bank BNK, and is located to at least partially cover the bank BNK, the first electrode EL1, and the light emitting diode LD. The insulating layer INS may be located to cover the entire surface of the first electrode EL1, and be located to cover a portion of the light emitting diode LD. At least a portion of an electrode layer 140 of the light emitting diode LD may be exposed by the insulating layer INS.

The insulating layer INS may include an inorganic material. In an example, the insulating layer INS may include at least one selected from silicon nitride (SiNx), silicon oxide (SiOx), silicon oxynitride (SiOxNy), and aluminum oxide (AlOx). In some embodiments, the insulating layer INS may include an organic material.

The second electrode EL2 is located on the insulating layer INS and the light emitting diode LD. The second electrode EL2 may cover the entire surface of the insulating layer INS, and be located to cover at least a portion of the light emitting diode LD. The second electrode EL2 may be a cathode. In one or more embodiments, the second electrode EL2 may be located on the electrode layer 140 of the light emitting diode LD, and be in direct contact with the electrode layer 140 of the light emitting diode LD. Accordingly, a second driving voltage of the second power source (VSS shown in FIG. 5), which is applied to the second electrode EL2, can be transferred to the light emitting diode LD.

In some embodiments, a protective layer may be provided on the second electrode EL2. The protective layer may include the same material as the insulating layer INS, but the present disclosure is not limited thereto. The protective layer may be provided on the second electrode EL2 to protect the second electrode EL2 from external oxygen, external moisture, etc. In some embodiments, at least one overcoat layer (e.g., a layer planarizing a top surface of the display element layer DPL) may be provided on the second electrode EL2.

In some embodiments, the display element layer DPL may selectively further include an optical layer in addition to the protective layer. In an example, the display element layer DPL may further include a color conversion layer including color conversion particles for converting light emitted from the light emitting diode LD into light of a set or specific color.

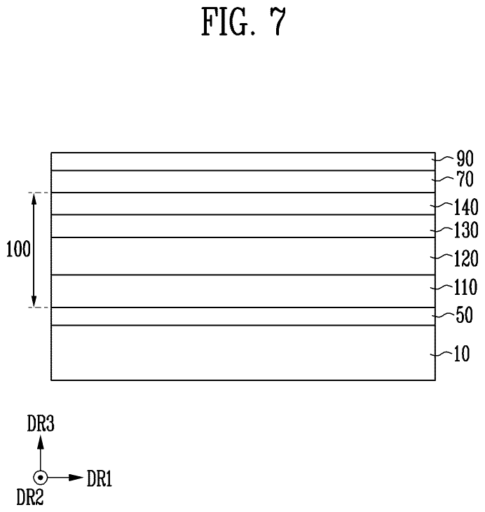

Hereinafter, a manufacturing method for a light emitting diode and a manufacturing method for a display device including the light emitting diode will be described with reference to FIGS. 7 to 17.

FIGS. 7 to 17 are sectional views illustrating a manufacturing method for a light emitting diode and a manufacturing method for a display device including the light emitting diode in accordance with one or more embodiments of the present disclosure.

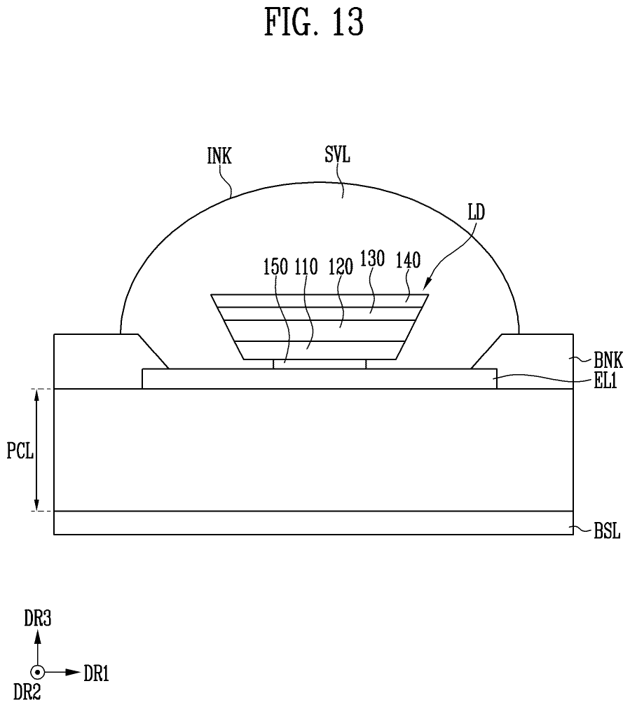

FIGS. 7 to 12 may correspond to the manufacturing method for the light emitting diode in accordance with one or more embodiments of the present disclosure, and FIGS. 13 to 17 correspond to the manufacturing method for the display device including the light emitting diode.

Referring to FIG. 7, a first sacrificial layer 50 may be formed on the stack substrate 10, and a first semiconductor layer 110, an active layer 120, a second semiconductor layer 130, an electrode layer 140, a second sacrificial layer 70, and a first bonding layer 90 may be sequentially formed on the first sacrificial layer 50. The first semiconductor 110, the active layer 120, the second semiconductor layer 130, and the electrode layer 140 may constitute a light emitting stack structure 100.

The stack substrate 10 may be a base substrate for stacking a target material. The stack substrate 10 may be a wafer for epitaxial growth of a set or predetermined material. In an example, the stack substrate 10 may be any one selected from a sapphire substrate, a GaAs substrate, a Ga substrate, and an InP substrate, but the present disclosure is not limited thereto. For example, when a material satisfies a selectivity for manufacturing a light emitting diode LD, and the epitaxial growth of the material may occur smoothly, the material may be selected as a material of the stack substrate 10. The surface of the stack substrate 10 may be smooth. The shape of the stack substrate 10 may be a polygonal shape such as a rectangular shape, or a circular shape, but the present disclosure is not limited thereto.

The first sacrificial layer 50 may be provided on the stack substrate 10. The first sacrificial layer 50 may allow the light emitting diode (LD shown in FIGS. 1 to 3) and the stack substrate 10 to be physically spaced apart from each other in a process of manufacturing the light emitting diode LD. The first sacrificial layer 50 may include any one selected from GaAs, AlAs, and AlGaAs. In an example, the first sacrificial layer 50 may include undoped GaN, but the present disclosure is not limited thereto. The first sacrificial layer 50 may be formed by any one method selected from among Metal Organic Chemical Vapor-phase Deposition (MOCVD), Molecular Beam Epitaxy (MBE), Vapor Phase Epitaxy (VPE), and Liquid Phage Epitaxy (LPE). However, the process of forming the first sacrificial layer 50 on the stack substrate 10 may be omitted according to selection of the process of manufacturing the light emitting diode LD.

The first semiconductor layer 110 may be formed on the first sacrificial layer 50. Similarly to the first sacrificial layer 50, the first semiconductor layer 110 may be formed through epitaxial growth, and be formed by any one selected from the methods exemplarily listed as the method for forming the first sacrificial layer 50. In an example, the first semiconductor layer 100 may include any one semiconductor material selected from among InAlGaN, GaN, AlGaN, InGaN, AlN, and InN, and may include an n-type semiconductor layer doped with a first conductive dopant such as Si, Ge and/or Sn. However, the material constituting the first semiconductor layer 110 is not limited thereto. In one or more embodiments, various suitable materials may constitute the first semiconductor layer 110. In some embodiments, a semiconductor layer for improving the crystallinity of the first semiconductor layer 110 may be additionally provided between the first sacrificial layer 50 and the first semiconductor layer 110.

The active layer 120 may be formed on the first semiconductor layer 110. The active layer 120 may be formed in a single or multiple quantum well structure. In one or more embodiments, a clad layer doped with a conductive dopant may be formed on the top and/or the bottom of the active layer 120. In an example, the clad layer may be formed as an AlGaN layer and/or an InAlGaN layer. In some embodiments, a material such as AlGaN and/or InAlGaN may be used to form the active layer 120. In one or more embodiments, various suitable materials may constitute the active layer 120.

The second semiconductor layer 130 may be formed on the active layer 120. The second semiconductor layer 130 may be configured as a semiconductor layer having a type (e.g., conductivity type) different from that of the first semiconductor layer 110. In an example, the second semiconductor layer 130 may include at least one semiconductor material selected from among InAlGaN, GaN, AlGaN, InGaN, AlN, and InN, and may include a p-type semiconductor layer doped with a second conductive dopant such as Mg, Zn, Ca, Sr and/or Ba. However, the material constituting the second semiconductor layer 130 is not limited thereto. In one or more embodiments, various suitable materials may constitute the second semiconductor layer 130.

The electrode layer 140 may be formed on the second semiconductor layer 130. In an example, the electrode layer 140 may include at least one selected from Cr, Ti, Al, Au, Ni, ITO, IZO, ITZO, any oxide thereof, and any alloy thereof. In one or more embodiments, the electrode layer 140 may include at least one selected from a metal which has an excellent (or suitable) electrical characteristic and a melting point of about 300° C. or lower, a fusible alloy, an eutectic alloy, and a soldering metal (e.g., a soldering metal for mounting a semiconductor chip). For example, the electrode layer 140 may include at least one selected from Sn, Bi, In, Ga, Sb, Pb, Cd, and any alloy thereof.

The first semiconductor layer 110, the active layer 120, the second semiconductor layer 130, and the electrode layer 140, which are sequentially stacked on the stack substrate 10 and the first sacrificial layer 50, may correspond to a part constituting the light emitting stack structure 100.

The second sacrificial layer 70 may be formed on the electrode layer 140. The second sacrificial layer 70 may include an inorganic material. In an example, the second sacrificial layer 70 may include silicon oxide (SiOx), silicon nitride (SiNx), silicon oxynitride (SiOxNy), etc. The second sacrificial layer 70 may allow the first bonding layer 90 and the light emitting stack structure 100 to be insulated from each other in the process of manufacturing the light emitting diode LD, and be removed in a lift-off process which will be described in more detail below.

The first bonding layer 90 may be formed on the second sacrificial layer 70. The first bonding layer 90, along with a second bonding layer 91 which will be described in more detail below, may allow the light emitting stack structure 100 and a carrier substrate 11 which will be described in more detail below to be adhered to each other. The first bonding layer 90 may include a material having a bonding force. In an example, the first bonding layer 90 may include a metal material, but the present disclosure is not limited thereto. In one or more embodiments, the first bonding layer 90 may further include an anti-diffusion metal layer on one surface of the first bonding layer 90 so as to prevent or reduce the diffusion of a component of a metal layer into the light emitting stack structure 100 due to heating and pressurization in the process of manufacturing the light emitting diode LD.

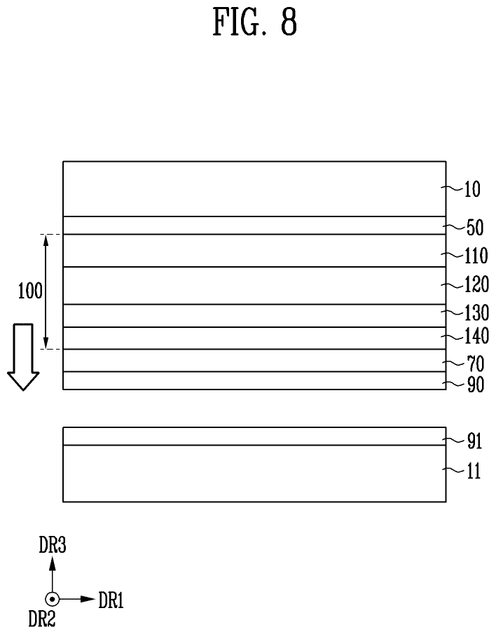

Referring to FIG. 8, the stack substrate 10 on which the light emitting stack structure 100 is formed and the carrier substrate 11 may be bonded together.

The carrier substrate 11 and the second bonding layer 91 formed on the carrier substrate 11 are prepared. In one or more embodiments, a stack structure in which the stack substrate 10, the first sacrificial layer 50, the light emitting stack structure 100, the second sacrificial layer 70, and the first bonding layer 90 are formed is turned upside down, so that the first bonding layer 90 and the second bonding layer 91 are located to face each other. Accordingly, the stack substrate 10 and the carrier substrate 11 may be bonded together by the first bonding layer 90 and the second bonding layer 91.

The carrier substrate 11 is a base supporting the stack substrate 10, and may be a wafer. In an example, the carrier substrate 11 may be any one selected from a quartz substrate, a glass substrate, a semiconductor substrate, a ceramic substrate, and a metal substrate, but the present disclosure is not limited thereto.

The second bonding layer 91 may be formed on the carrier substrate 11. The second bonding layer 91 along with the first bonding layer 90 may allow the light emitting stack structure 100 and the carrier substrate 11 to be adhered to each other. The second bonding layer 91 may include a material having a bonding force. In an example, the second bonding layer 91 may include a metal material, but the present disclosure is not limited thereto. In one or more embodiments, the second bonding layer 91 may further include an anti-diffusion metal layer on one surface of the second bonding layer 91 so as to prevent or reduce the diffusion of a component of a metal layer into the light emitting stack structure 100 due to heating and pressurization in the process of manufacturing the light emitting diode LD.

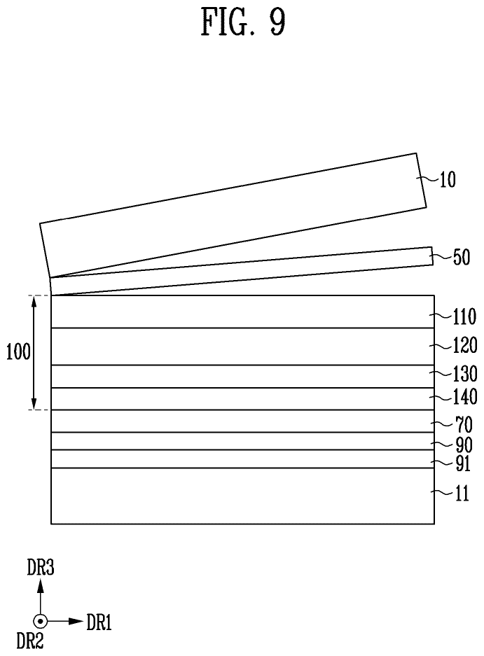

Referring to FIG. 9, the stack substrate 10 and the first sacrificial layer 50, which are located at an upper portion of the stack structure, may be removed.

The stack substrate 10 and the first sacrificial layer 50 may be removed through a polishing or etching process. First, after the surface of the stack substrate 10 is removed through the polishing process, the remaining stack substrate 10 with a set or predetermined thickness and the first sacrificial layer 50 may be removed through the etching process. The stack substrate 10 and the first sacrificial layer 50 may be etched by using wet etching, and be selectively etched by using a solution such as HF and/or KOH. However, the present disclosure is not limited thereto, and the stack substrate 10 and the first sacrificial layer 50 may be removed through a dry etching process.

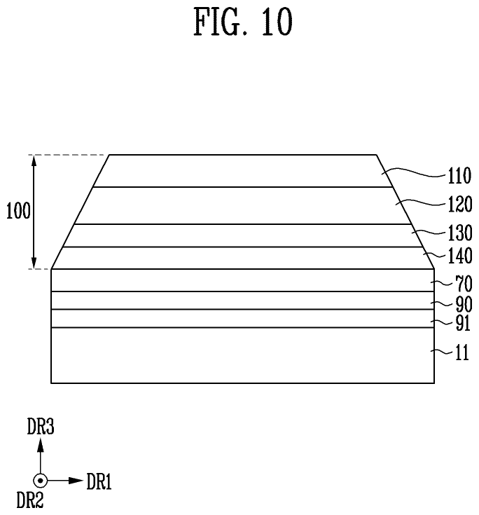

Referring to FIG. 10, the first semiconductor layer 110, the active layer 120, the second semiconductor layer 130, and the electrode layer 140, which constitute the light emitting diode (LD shown in FIGS. 1 to 3), may be formed by etching the light emitting stack structure 100 in (e.g., along) a third direction DR3.

The first semiconductor layer 110, the active layer 120, the second semiconductor layer 130, and the electrode layer 140 may be etched at different etching selectivities along the third direction DR3. In an example, an area of the first semiconductor layer 110 located at an uppermost end of the light emitting stack structure 100 shown in FIG. 10 may be formed narrower (e.g., smaller) than that of the electrode layer 140 located at a lowermost end of the light emitting diode LD. The first semiconductor layer 110, the active layer 120, the second semiconductor layer 130, and the electrode layer 140 may be formed such that both side edges of the first semiconductor layer 110, the active layer 120, the second semiconductor layer 130, and the electrode layer 140 are respectively located on a straight line having the same slope. In an example, the light emitting stack structure 100 may be formed in a truncated pyramid shape.

A dry etching process may be applied to the etching process for forming the light emitting diode LD. In an example, the dry etching process may be any one selected from Reactive Ion Etching (RIE), Reactive Ion Beam Etching (RIBE), and Inductively Coupled Plasma Reactive Ion Etching (ICP-RIE), but the present disclosure is not limited thereto. Unlike the wet etching process, the dry etching process may be suitable for forming a portion of the light emitting diode LD because isotropic etching is easily implemented through the dry etching process.

After the etching process for forming the light emitting diode LD, a residue remaining on the light emitting diode LD may be removed by an ordinary removal method. The residue may be an etching mask, an insulating material, and/or the like, which is required in a mask process. In some embodiments, after the etching process for forming the light emitting diode LD, a wet etching process of removing a damaged surface of the light emitting diode LD may be performed.

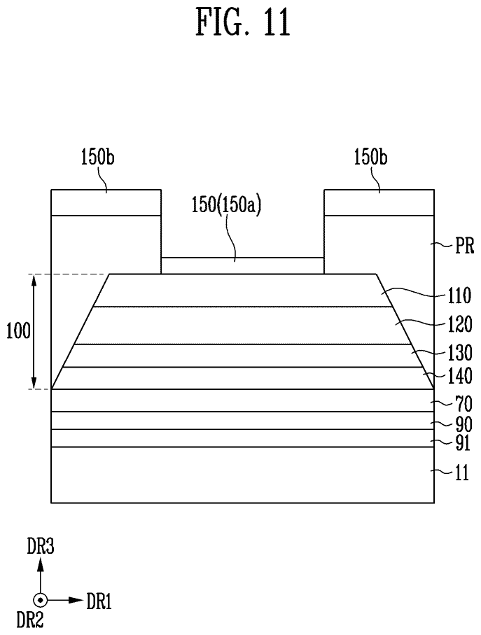

Referring to FIG. 11, a photoresist pattern PR may be formed at both side surfaces of the light emitting stack structure 100 by coating a photosensitive material on the light emitting stack structure 100 and performing a photo process (e.g., a photo etching process) using a mask, and a bonding electrode layer 150 may be formed on each of the formed photoresist pattern PR and the light emitting stack structure 100.

The photoresist pattern PR may be coated to overlap with each of at least a portion of the upper surface of the light emitting stack structure 100 and both side surfaces of the light emitting stack structure 100. For example, the photoresist pattern PR may be formed to overlap with each of at least a portion of the upper surface of the first semiconductor layer 110 and the side edge of the first semiconductor layer 110.

The bonding electrode layer 150 may include a first bonding electrode layer 150a and a second bonding electrode layer 150b. The first bonding electrode layer 150a and the second bonding electrode layer 150b may be divided according to areas in which the first bonding electrode layer 150a and the second bonding electrode layer 150b are formed. The first bonding electrode layer 150a may be formed on the upper surface of the light emitting stack structure 100. The second bonding electrode layer 150b may be formed on the upper surface of the photoresist pattern PR. The light emitting diode LD manufactured through such a process may be the above-described light emitting diode LD shown in FIG. 1.

In some embodiments, in the above-described photo process (e.g., photo etching process), the photoresist pattern PR may be in contact with the side edge of the first semiconductor layer 110, and be formed not to be located on a top surface of the first semiconductor layer 110. The bonding electrode layer 150 may be formed on only the upper surface of the light emitting stack structure 100. The light emitting diode LD manufactured through such a process may be the above-described light emitting diode LD shown in FIG. 2.

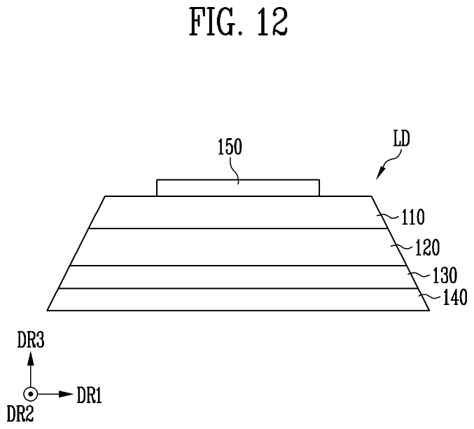

Referring to FIG. 12, the light emitting diode LD may be separated from the carrier substrate 11, the first bonding layer 90, the second bonding layer 91, and the second sacrificial layer 70. In an example, the light emitting diode LD may be separated through a Laser Lift-Off (LLO) process or a Chemical Lift-Off (CLO) process. The photoresist pattern PR may be removed, and a residue of the second sacrificial layer 70, which may remain on the bottom of the electrode layer 140 may be removed. The second sacrificial layer 70 may be removed by using an HF and/or buffered oxide etchant (BOE) solution.

Referring to FIG. 13, a pixel circuit layer PCL, a first electrode EL1, and a bank BNK may be formed on a base layer BSL, and an ink INK may be sprayed on the first electrode EL1. The ink INK may include a solvent SVL and a solid, and the solid may include a plurality of light emitting diodes LD. The solvent SVL is made of acetone, water, alcohol, PGMEA (Propylene Glycol Methyl Ether Acetate), toluene, etc., and may be a material which is evaporated and/or volatilized at room temperature or by heat.

In one or more embodiments, because the light emitting diode LD corresponds to a structure having a width longer than a length thereof, an upper surface or a lower surface of the light emitting diode LD, which has a relatively wide area, may be located to face the first electrode EL1. For example, when the light emitting diode LD has a truncated pyramid shape, the light emitting diode LD corresponds to a structure having an upper surface and a lower surface, which have different areas. Therefore, the first semiconductor layer 110 and the bonding electrode layer 150, which have a relatively narrow (e.g., smaller) area, may be positioned to face the first electrode EL1. For example, with respect to the third direction DR3, the bonding electrode layer 150 may be located at the lower surface of the light emitting diode LD, and the electrode layer 140 may be located at the upper surface of the light emitting diode LD. The bonding electrode layer 150 of the light emitting diode LD is on the first electrode EL1, so that the bonding electrode layer 150 and the first electrode EL1 can be in direct contact with each other. Thus, the light emitting diode LD and the first electrode EL1 can be physically and/or electrically connected (e.g., physically and/or electrically coupled) to each other. A driving voltage and/or current applied through the first electrode EL1 can be stably (or suitably) transferred to the light emitting diode LD.

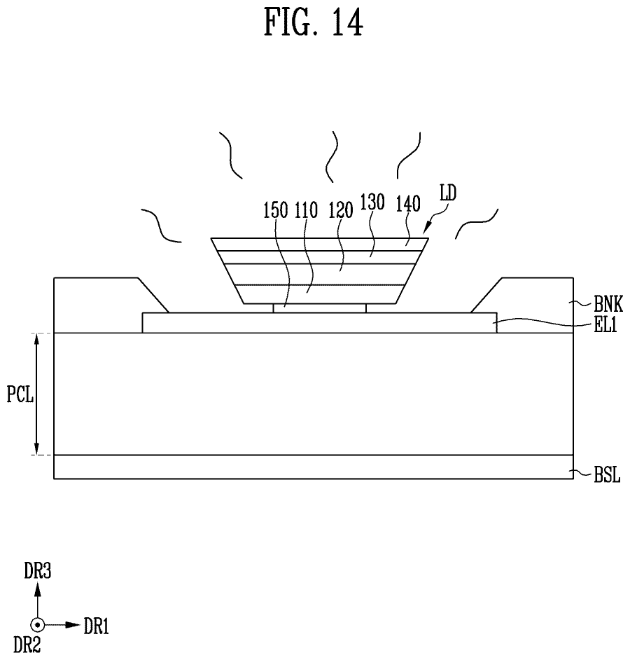

Referring to FIG. 14, after the light emitting diode LD is aligned, the solvent SVL may be volatilized. The bonding electrode layer 150 of the light emitting diode LD may be adhered closely to the first electrode EL1 connected (e.g., physically coupled) to the pixel circuit layer PCL, and accordingly, the light emitting diode LD can be stably arranged on the pixel circuit layer PCL. The solvent SVL may be evaporated or volatilized at room temperature or by heat.

The bonding force between the light emitting diode LD and the first electrode EL1 can be improved when a process temperature becomes high.

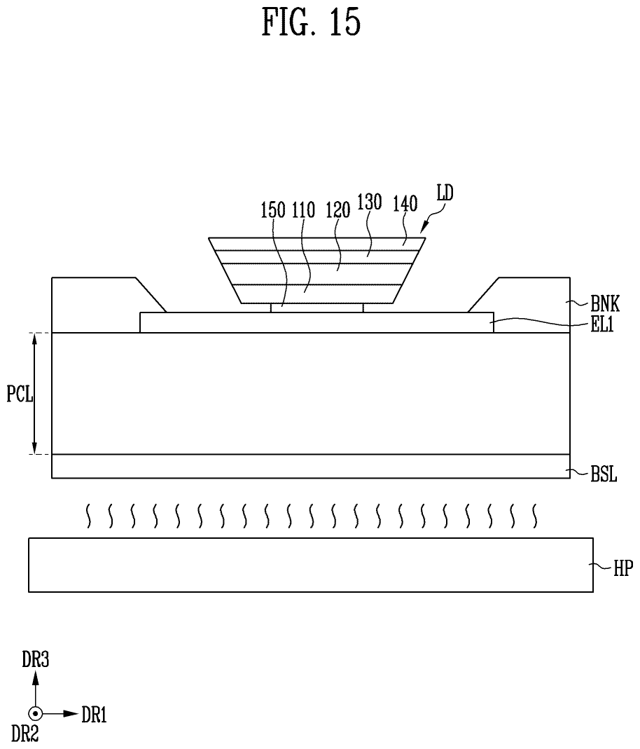

Referring to FIG. 15, the bonding force between the light emitting diode LD and the first electrode EL1 may be improved by using a heating part HP. In an example, the heating part HP may be a hot plate.

The heating part HP is located under the base layer BLS, and heat is applied, so that the bonding force between the bonding electrode layer 150 of the light emitting diode LD and the first electrode EL1 can be improved. For example, a temperature may be increased to a degree in which the bonding electrode layer 150 of the light emitting diode LD can become a gel.

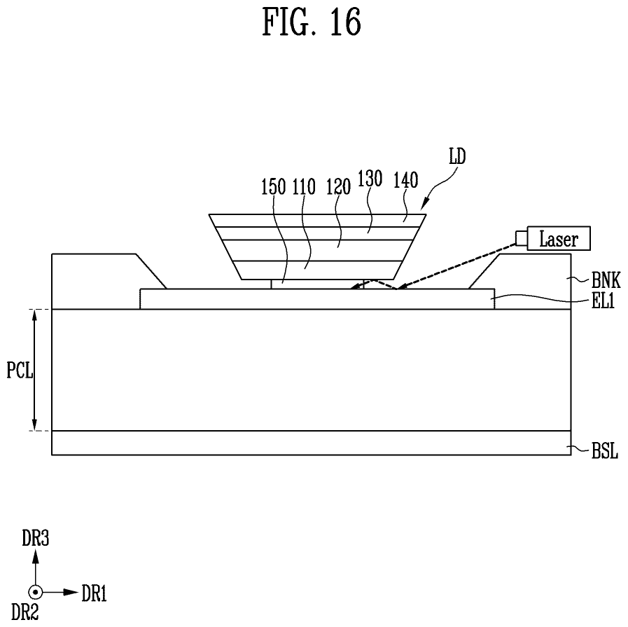

Referring to FIG. 16, the bonding force between the light emitting diode LD and the first electrode EL1 may be improved by using a laser Laser.

The laser Laser is located between the light emitting diode LD and the first electrode EL1, and a laser beam having a wavelength in a range in which the bonding electrode layer 150 can be melted is irradiated onto a boundary surface at which the bonding electrode layer 150 and the first electrode EL1 are bonded to each other, so that the bonding force between the bonding electrode layer 150 of the light emitting diode LD and the first electrode EL1 can be improved.

As described above, the light emitting diode LD in accordance with the embodiments of the present disclosure includes the bonding electrode layer 150, so that the adherence between the light emitting diode LD and the first electrode EL1 can be improved. Thus, a driving voltage and/or current applied through the first electrode EL1 can be stably (or suitably) transferred to the light emitting diode LD.

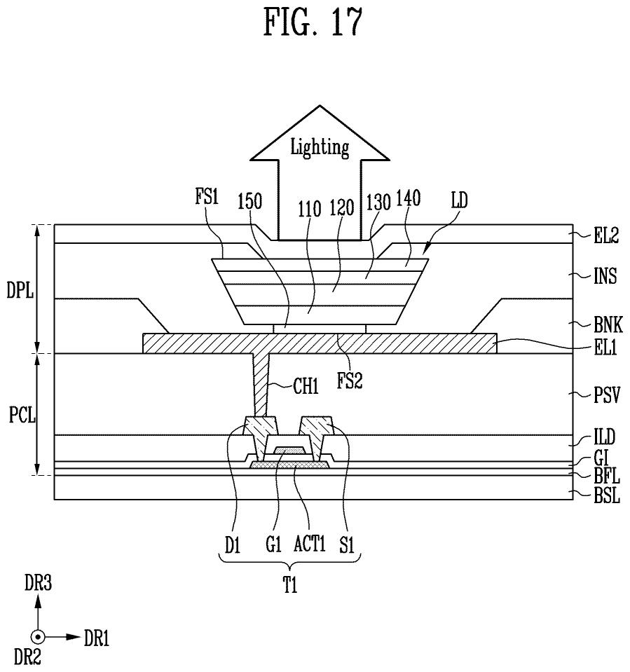

Referring to FIG. 17, an insulating layer INS is formed to cover the first electrode EL1 and the bank BNK, and is formed to cover at least a portion of the light emitting diode LD.

The insulating layer INS may include an inorganic material. In an example, the insulating layer INS may include at least one selected from silicon nitride (SiNx), silicon oxide (SiOx), silicon oxynitride (SiOxNy), and aluminum oxide (AlOx). In some embodiments, the insulating layer INS may include an organic material.

Subsequently, a second electrode EL2 is formed on the upper surface of the light emitting diode LD, which is exposed by the insulating layer INS, and the insulating layer INS. The second electrode EL2 may be in direct contact with the electrode layer 140 of the light emitting diode LD, to be physically and/or electrically connected (e.g., physically and/or electrically coupled) to the electrode layer 140.

In the display device formed through the above-described manufacturing method, a drain electrode D1 of the pixel circuit layer PCL may be physically and/or electrically connected (e.g., physically and/or electrically coupled) to the first electrode EL1 through a first contact hole CH1. Accordingly, the first driving voltage of the first power source (VDD shown in FIG. 5) from a first transistor T1 can be applied to the first electrode EL1. Because the first electrode EL1 is in direct contact with the light emitting diode LD, the first electrode EL1 and the light emitting diode LD can be physically and/or electrically connected (e.g., physically and/or electrically coupled) to each other, and the first electrode EL1 can transfer the first driving voltage of the first power source VDD to one side of the light emitting diode LD. In one or more embodiments, because the second electrode EL2 is in direct contact with the light emitting diode LD, the second electrode EL2 and the light emitting diode LD can be physically and/or electrically connected (e.g., physically and/or electrically coupled) to each other, and the second electrode EL2 can transfer the second driving voltage of the second power source (VSS shown in FIG. 5) to the other side of the light emitting diode LD. Accordingly, the light emitting diode LD emits light, so that the light can be emitted in the third direction DR3.

In one or more embodiments, the light emitting diode LD includes the bonding electrode layer 150, so that the bonding force between the light emitting diode LD and the first electrode EL1 can be improved. Thus, a driving voltage and/or current applied through the first electrode EL1 can be stably (or suitably) transferred to the light emitting diode LD.

Hereinafter, a light emitting diode and a display device including the same in accordance with one or more embodiments of the present disclosure will be described.

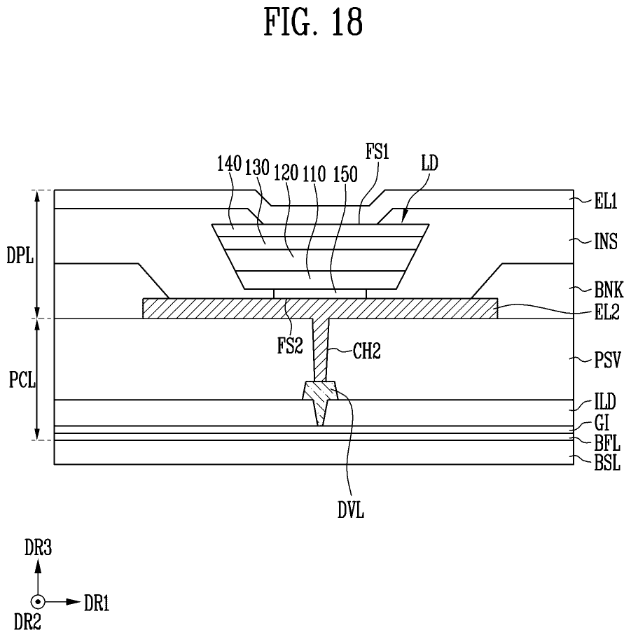

FIG. 18 is a schematic sectional view of a light emitting diode and a display device including the same in accordance with one or more embodiments of the present disclosure. The light emitting diode in accordance with the embodiment of the present disclosure, which is shown in FIG. 18, is similar to the light emitting diode described in FIG. 2, and the display device in accordance with the embodiment of the present disclosure, which is shown in FIG. 18, is similar to the display device shown in FIG. 6. Therefore, overlapping descriptions will not be provided.

Referring to FIG. 18, first, the light emitting diode LD in accordance with the embodiments of the present disclosure may include a first semiconductor layer 110, an active layer 120, a second semiconductor layer 130, an electrode layer 140, and a bonding electrode layer 150.

The light emitting diode LD may be configured as a stack structure in which the bonding electrode layer 150, the first semiconductor layer 110, the active layer 120, the second semiconductor layer 130, and the electrode layer 140 are sequentially stacked along a height direction (or third direction DR3).

In one or more embodiments, the electrode layer 140 may be at a first surface FS1 of the light emitting diode LD, and the bonding electrode layer 150 may be at a second surface FS2 of the light emitting diode LD. In one or more embodiments, the bonding electrode layer 150 may be at the first surface FS1 of the light emitting diode LD, and the electrode layer 140 may be at the second surface FS2 of the light emitting diode LD.

The first semiconductor layer 110 may be a semiconductor layer having a second conductivity (or type). In an example, the first semiconductor layer 110 may include at least one p-type semiconductor. For example, the first semiconductor layer 110 may include at least one semiconductor material selected from among InAlGaN, GaN, AlGaN, InGaN, AlN, and InN, and may include a p-type semiconductor layer doped with a second conductive dopant such as Mg, Zn, Ca, Sr and/or Ba.

The active layer 120 may be on one surface of the first semiconductor layer 110. The active layer 120 may be on the first semiconductor layer 110. The active layer 120 may be formed in a single or multiple quantum well structure. In one or more embodiments, a clad layer doped with a conductive dopant may be formed on the top and/or the bottom of the active layer 120. In an example, the clad layer may be formed as an AlGaN layer and/or an InAlGaN layer. In some embodiments, a material such as AlGaN and/or InAlGaN may be used to form the active layer 120. In one or more embodiments, various suitable materials may constitute the active layer 120.

The second semiconductor layer 130 is formed on one surface of the active layer 120. The second semiconductor layer 130 may be on the active layer 120. The second semiconductor layer 130 may include a semiconductor layer having a conductivity (or type) different from that of the first semiconductor layer 110. In an example, the second semiconductor layer 130 may include at least one n-type semiconductor layer. For example, the second semiconductor layer 13 may include at least one semiconductor material selected from among InAlGaN, GaN, AlGaN, InGaN, AlN, and InN, and may include an n-type semiconductor layer doped with a first conductive dopant such as Si, Ge and/or Sn. However, the material constituting the second semiconductor layer 130 is not limited thereto. In one or more embodiments, various suitable materials may constitute the second semiconductor layer 130.

The electrode layer 140 is on one surface of the second semiconductor layer 130. The electrode layer 140 may be on the second semiconductor layer 130. The electrode layer 140 may include a metal and/or a metal oxide. In an example, the electrode layer 140 may include at least one selected from Cr, Ti, Al, Au, Ni, ITO, IZO, ITZO, any oxide thereof, and any alloy thereof. In one or more embodiments, the electrode layer 140 may include at least one selected from a metal which has an excellent (or suitable) electrical characteristic and a melting point of about 300° C. or lower, a fusible alloy, an eutectic alloy, and a soldering metal (e.g., a soldering metal for mounting a semiconductor chip). For example, the electrode layer 140 may include at least one selected from Sn, Bi, In, Ga, Sb, Pb, Cd, and any alloy thereof.

In some embodiments, the electrode layer 140 may be substantially transparent or translucent. Accordingly, light generated in the light emitting diode LD may be transmitted through the electrode layer 140 and then emitted to the outside of the light emitting diode LD. The electrode layer 140 may be in direct contact with a first electrode EL1 (e.g., an anode) of a display element layer DPL.

The bonding electrode layer 150 is on one surface of the first semiconductor layer 110. The bonding electrode layer 150 may be under the first semiconductor layer 110. The bonding electrode layer 150 may include a metal and/or a metal oxide. In an example, the bonding electrode layer 150 may include at least one selected from a metal which has an excellent (or suitable) electrical characteristic and a melting point of about 300° C. or lower, a fusible alloy, and an eutectic alloy. For example, the bonding electrode layer 150 may include at least one selected from Sn, Bi, In, Ga, Sb, Pb, Cd, and any alloy thereof. The bonding electrode layer 150 may also include a soldering metal (e.g., a soldering metal for mounting a semiconductor chip). In one or more embodiments, the bonding electrode layer 150 may include at least one selected from Cr, Ti, Al, Au, Ni, ITO, IZO, ITZO, any oxide thereof, and any alloy thereof. For example, the electrode layer 140 and the bonding electrode layer 150 may include the same material or include different materials.

In some embodiments, the bonding electrode layer 150 may be substantially transparent or translucent. Accordingly, light generated in the light emitting diode LD may be transmitted through the bonding electrode layer 150 and then emitted to the outside of the light emitting diode LD. The electrode layer 140 may be in direct contact with a second electrode EL2 (e.g., a cathode) of the display element layer DPL. For example, because the bonding electrode layer 150 is in direct contact with the second electrode EL2, the bonding electrode layer 150 can stably (or suitably) transfer a driving voltage and/or current to the first semiconductor layer 110, etc. of the light emitting diode LD. Accordingly, the bonding force between the light emitting diode LD and the second electrode EL2 is improved, so that the display device having improved luminance, improved lifetime, improved yield, and/or the like can be implemented.

The display device in accordance with the embodiments of the present disclosure may include a base layer BSL, a pixel circuit layer PCL, and the display element layer DPL.

The pixel circuit layer PCL is located on the base layer BSL. The pixel circuit layer PCL may include a buffer layer BFL, a gate insulating layer GI, an interlayer insulating layer ILD, a driving voltage line DVL, and a passivation layer PSV.

The gate insulating layer GI is located on the buffer layer BFL to cover the buffer layer BFL. The gate insulating layer GI may include an inorganic material. In an example, the gate insulating layer GI may include at least one selected from silicon nitride (SiNx), silicon oxide (SiOx), silicon oxynitride (SiOxNy), and aluminum oxide (AlOx). In some embodiments, the gate insulating layer GI may include an organic material.

The interlayer insulating layer ILD is located on the gate insulating layer GI to cover the gate electrode G1. The interlayer insulating layer ILD may include the same material as the gate insulating layer GI. In an example, the interlayer insulating layer ILD may include at least one selected from silicon nitride (SiNx), silicon oxide (SiOx), silicon oxynitride (SiOxNy), and aluminum oxide (AlOx).

The driving voltage line DVL is located on the interlayer insulating layer ILD. The driving voltage line DVL may be a portion of the second voltage line PL2 shown in FIG. 5. Therefore, the driving voltage line DVL may transfer the second driving voltage of the second power source (VSS shown in FIG. 5) to the second electrode EL2.

The passivation layer PSV is located over the driving voltage line DVL. The passivation layer PSV may include an inorganic material and/or an organic material. The driving voltage line DVL may be physically and/or electrically connected (e.g., physically and/or electrically coupled) to the second electrode EL2 of the display element layer DPL through a second contact hole CH2 of the passivation layer PSV.

The display element layer DPL is located on the pixel circuit layer PCL. The display element layer DPL may include the second electrode EL2, a bank BNK, the light emitting diode LD, an insulating layer INS, and the first electrode EL1.

The second electrode EL2 is located on the passivation layer PSV of the pixel circuit layer PCL. The second electrode EL2 may be a cathode. The second electrode layer EL2 may be physically and/or electrically connected (e.g., physically and/or electrically coupled) to the driving voltage line DVL of the pixel circuit layer PCL through the second contact hole CH2 of the passivation layer PSV. Accordingly, the second electrode EL2 can be applied with the voltage of the second power source (VSS shown in FIG. 5).

The second electrode EL2 may include a transparent conductive material. In an example, the second electrode EL2 may include Cu, Au, Ag, Mg, Al, Pt, Pb, Ni, Nd, Ir, Cr, Li, Ca, any mixture thereof, ITO, IZO, ZnO, ITZO, etc., but the present disclosure is not limited thereto.

The bank BNK may be located on the passivation layer PSV of the pixel circuit layer PCL. The bank BNK may be a structure capable of partitioning each pixel area. The second electrode EL2, the light emitting diode LD, and/or the like may be located between two adjacent banks BNK. The bank BNK may include an organic material.

The light emitting diode LD is located on the second electrode EL2. In one or more embodiments, the bonding electrode layer 150 of the light emitting diode LD may be located on the second electrode EL2, and the second electrode EL2 and the bonding electrode layer 150 of the light emitting diode LD may be in direct contact with each other. Accordingly, the second driving voltage of the second power source (VSS shown in FIG. 5), which is applied to the second electrode EL2, can be transferred to the light emitting diode LD.

The insulating layer INS is located over the bank BNK, and is located to at least partially cover the bank BNK, the second electrode EL2, and the light emitting diode LD. The insulating layer INS may be located to cover the entire surface of the second electrode EL2, and be located to cover a portion of the light emitting diode LD. At least a portion of an electrode layer 140 of the light emitting diode LD may be exposed by the insulating layer INS. The electrode layer 140 of the light emitting diode LD may be in direct contact with the first electrode EL1 by (e.g., through) the exposed portion of the insulating layer INS.

The insulating layer INS may include an inorganic material. In an example, the insulating layer INS may include at least one selected from silicon nitride (SiNx), silicon oxide (SiOx), silicon oxynitride (SiOxNy), and aluminum oxide (AlOx). In some embodiments, the insulating layer INS may include an organic material.

The first electrode EL1 is located on the insulating layer INS and the light emitting diode LD. The first electrode EL1 may cover the entire surface of the insulating layer INS, and be located to cover at least a portion of the light emitting diode LD. The first electrode EL1 may be an anode. In one or more embodiments, the first electrode EL1 may be located on the electrode layer 140 of the light emitting diode LD, and be in direct contact with the electrode layer 140 of the light emitting diode LD. Accordingly, the first driving voltage of the first power source (VDD shown in FIG. 5), which is applied to the first electrode EL1, can be transferred to the light emitting diode LD.

In one or more embodiments, the first electrode EL1 is in direct contact with the electrode layer 140 of the light emitting diode LD, so that a driving voltage and/or current can be stably (or suitably) transferred to the second semiconductor layer 130, etc. of the light emitting diode LD. Accordingly, the bonding force between the light emitting diode LD and the first electrode EL1 is improved, so that the display device having improved luminance, improved lifetime, improved yield, and/or the like can be implemented.

In accordance with the present disclosure, there can be provided a light emitting diode, a manufacturing method for the same, a display device including a light emitting diode, and a manufacturing method for the same, in which the bonding force between the light emitting diode and a first electrode (e.g., an anode) is improved by using a bonding electrode layer included in the light emitting diode, so that the display device can have improved luminance, improved lifetime, improved yield, and/or the like.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used alone or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims and their equivalents.

What is claimed is:

1. A light emitting diode comprising:
a first semiconductor layer;
an active layer on a first surface of the first semiconductor layer;
a second semiconductor layer on one surface of the active layer;
an electrode layer on one surface of the second semiconductor layer, wherein light is to be emitted through the electrode layer; and
a bonding electrode layer on a second surface of the first semiconductor layer that is opposite to the first surface,
wherein both side edges of each of the first semiconductor layer, the active layer, the second semiconductor layer, and the electrode layer are respectively located on a straight line having a same slope,
wherein an area of the first semiconductor layer is smaller than an area of the electrode layer, and
wherein an entire interface between the first semiconductor layer and the bonding electrode layer is substantially flat.

2. The light emitting diode of claim 1, wherein the bonding electrode layer comprises at least one selected from a metal having a melting point of 300° C. or lower, a fusible alloy, an eutectic alloy, and a soldering metal to mount a semiconductor chip.

3. The light emitting diode of claim 1, wherein the first semiconductor layer comprises at least one n-type semiconductor,
wherein the second semiconductor layer comprises at least one p-type semiconductor, and
wherein the bonding electrode layer is under the first semiconductor layer, and the electrode layer is on the second semiconductor layer.

4. The light emitting diode of claim 1, wherein the first semiconductor layer comprises at least one p-type semiconductor,
wherein the second semiconductor layer comprises at least one n-type semiconductor, and
wherein the bonding electrode layer is under the first semiconductor layer, and the electrode layer is on the second semiconductor layer.

5. The light emitting diode of claim 1, wherein the light emitting diode has a shape in which a width in a horizontal direction thereof is longer than a height in a vertical direction thereof.

6. A display device comprising:
a base layer;
a pixel circuit layer on the base layer, the pixel circuit layer comprising a first transistor; and
a display element layer on the pixel circuit layer, the display element layer comprising a light emitting diode, a first electrode to which a first driving voltage is applied, and a second electrode to which a second driving voltage is applied,
wherein the light emitting diode comprises:
a first semiconductor layer;
an active layer on a first surface of the first semiconductor layer;
a second semiconductor layer on one surface of the active layer;
an electrode layer on one surface of the second semiconductor layer; and
a bonding electrode layer on a second surface of the first semiconductor layer that is opposite to the first surface,
wherein the electrode layer is electrically coupled to the second electrode, and
the bonding electrode layer is electrically coupled to the first electrode,
wherein the first electrode is larger in width than the bonding electrode layer,
wherein an area of the first semiconductor layer is smaller than an area of the electrode layer, and
wherein an entire interface between the first semiconductor layer and the bonding electrode layer is substantially flat.

7. The display device of claim 6, wherein the first semiconductor layer comprises one selected from at least one n-type semiconductor and at least one p-type semiconductor, and
the second semiconductor layer comprises the other selected from the at least one p-type semiconductor and the at least one n-type semiconductor.

8. The display device of claim 6, wherein the first transistor comprises a gate electrode, an active layer, a source electrode, and a drain electrode, and
wherein the drain electrode of the first transistor is electrically coupled to the first electrode.

9. The display device of claim 6, wherein the bonding electrode layer is on the first electrode, and
wherein the first electrode and the bonding electrode layer are in direct contact with each other.

10. The display device of claim 9, wherein the bonding electrode layer comprises at least one selected from a metal having a melting point of 300° C. or lower, a fusible alloy, an eutectic alloy, and a soldering metal to mount a semiconductor chip.

11. The display device of claim 6, wherein the electrode layer is under the second electrode, and
wherein the second electrode and the electrode layer are in direct contact with each other.
